(19) United States
(12) Patent Application Publication
(10) Pub. No.: US 2026/0026344 A1
(43) Pub. Date: Jan. 22, 2026

(54) INTEGRATED CIRCUIT PACKAGE

(71) Applicant: STMicroelectronics International N.V., Geneva (CH)

(72) Inventors: Asma HAJJI, Voiron (FR); Ouafa HAJJI, Voiron (FR); Fabien QUERCIA, Saint Marcellin (FR); Younes BOUTALEB, Grenoble (FR)

(73) Assignee: STMicroelectronics International N.V., Geneva (CH)

(21) Appl. No.: 19/270,850

(22) Filed: Jul. 16, 2025

(30) Foreign Application Priority Data
Jul. 19, 2024 (FR) FR2407995

(51) Int. Cl. H01L 23/373; H01L 21/52; H01L 23/00; H01L 23/04

(52) U.S. Cl. CPC H01L 23/3737; H01L 21/52; H01L 23/04; H01L 24/29; H01L 24/32; H01L 24/83; H01L 2224/2919; H01L 2224/32245; H01L 2224/83447

(57) ABSTRACT

A chip is assembled on an interconnection substrate. A heat dissipation layer made of a thermal interface material is deposited on the chip. A cap is bonded to the substrate with the cap covering the chip and the heat dissipation layer contacting with the cap. An element made of an adhesive material or a solderable material is formed on the chip prior to depositing the heat dissipation layer, or formed on the cap prior to bonding the cap. The element is thus in contact with the cap and with the chip and positioned next to the heat dissipation layer.

### PRIORITY CLAIM

This application claims the priority benefit of French Application for Patent No. FR2407995 filed on Jul. 19, 2024, the content of which is hereby incorporated by reference in its entirety to the maximum extent allowable by law.

### TECHNICAL FIELD

The present disclosure generally concerns electronic components and, more particularly, integrated circuit packages, for example packages of ball grid array (BGA) type, and the mounting of electronic chips in these packages.

### BACKGROUND

Ball grid array (BGA) type packages enable to electrically integrate an electronic chip to an external component, such as, for example, a printed circuit board (PCB).

With the miniaturization of electronic components, heat dissipation management becomes more and more critical. To improve the thermal performance of electronic components, packages comprise a thermally-conductive cap (or cover) positioned over the chip and bonded to the substrate. The cover enables to help dissipating the heat generated by the chip.

The presence of a thermal interface material (TIM) positioned on the chip and in contact with the cover can facilitate heat dissipation.

There exists a need to improve packages for electronic chips and, in particular, to improve the heat dissipation of these packages.

### SUMMARY

In an embodiment, a method of manufacturing an electronic device comprises the following steps:

a) providing an assembly comprising a chip and an interconnection substrate, the chip having a first surface and a second surface, the first surface of the chip being assembled to the interconnection substrate by contact pads; b) depositing a heat dissipation layer made of a thermal interface material on the second surface of the chip; c) bonding a cap to the substrate, the cap covering the chip, the heat dissipation layer being in contact with the cap; the method further comprising a step d) during which an element made of an adhesive material or of a solderable material is formed either on the chip, prior to step b), or on the cap, prior to step c), so that, during step c), the element is in contact with the cap and with the chip and is positioned next to the heat dissipation layer.

According to a specific embodiment, the element is made of a B-stage polymer material.

According to a specific embodiment, during step d), the B-stage polymer material is deposited and then pre-polymerized, and, during step c) or after step c), the B-stage material is polymerized.

According to a specific embodiment, the element is made of a thermal interface material, identical to or different from the thermal interface material of the heat dissipation layer.

According to a specific embodiment, the element is made of a solderable material, the element being ultrasonically soldered to one of the cap or of the second surface of the chip during step d) and to the other one of the cap or of the second surface of the chip during step c) or after step c).

In an embodiment, an electronic device comprises: an electronic chip arranged between an interconnection substrate and a cap; a first surface of the electronic chip comprising contact pads bonded to the interconnection substrate; a heat dissipation layer; and an element made of an adhesive material or of a solderable material being positioned on a second surface of the chip and in contact with the cap.

According to a specific embodiment, the element is made of a B-stage polymer material, preferably selected from among polyepoxides.

According to a specific embodiment, the element is made of a thermal interface material, identical to or different from the thermal interface material of the heat dissipation layer.

According to a specific embodiment, the element forms strips or pads, positioned around the heat dissipation layer.

According to a specific embodiment, the cap is a metal cap, preferably made of copper.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIGS. 1 to 4 schematically show various steps of a method of manufacturing an integrated circuit package;

FIG. 5 schematically shows a variant of a step of a method of manufacturing an integrated circuit package;

FIG. 6A, FIG. 6B, FIG. 6C, and FIG. 6D respectively show, schematically and in top view, a chip, on a substrate, locally covered by an adhesive element or by a solderable element; and

FIG. 7 schematically shows in cross-section view an integrated circuit package.

### DETAILED DESCRIPTION

In the various drawings, the different elements and components are not necessarily shown to the same scale as one another.

The same elements have been designated by the same references in the various figures. Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

By in the range from X to Y, there is meant that limits X and Y are included, which is equivalent to at least X and up to and including Y.

By B-stage polymer material, there is meant a polymer material with multiple polymerization steps. The final polymer material is sequentially formed by a polymerization method in a plurality of steps. A first polymerization step results in the obtaining of a pre-polymerized (that is, partially polymerized) material. The pre-polymerized material exhibits a first degree of polymerization. It is at polymerization stage A. This first step enables to “set” the material, while leaving a given adhesiveness thereto. A second and final polymerization step results in the obtaining of a polymerized material, preferably fully polymerized (polymerization stage B). The degree of polymerization of stage B is greater than the first degree of polymerization of stage A. The polymerized material is rigid and adheres to the elements with which it is in contact.

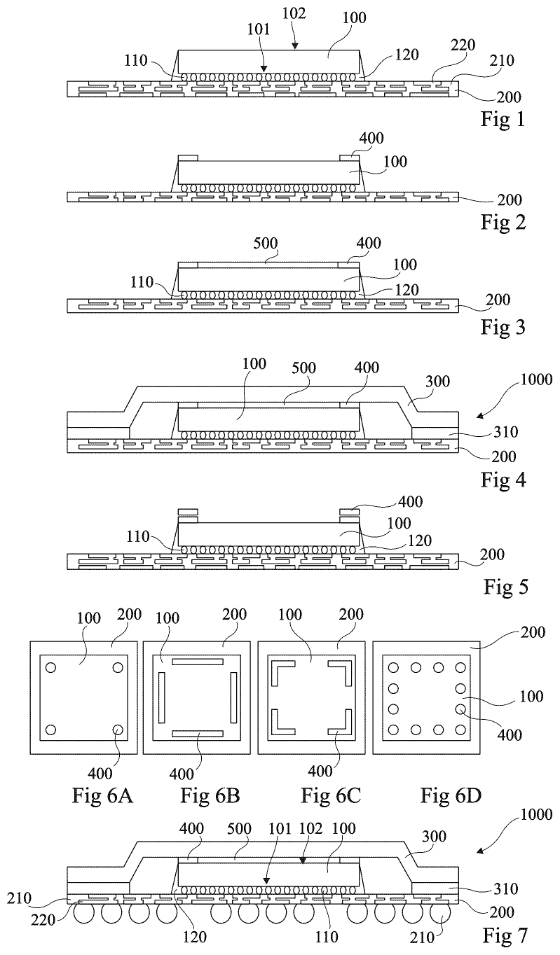

The method of manufacturing an integrated circuit package will now be described with reference to FIGS. 1 to 4.

The method comprises the following steps: a) providing an assembly comprising a chip 100 having a first surface 101 and a second surface 102, the first surface 101 of chip 100 being assembled to a substrate 200 via connection pads 110 (FIG. 1); b) depositing a heat dissipation layer 500 made of a thermal interface material on the second surface 102 of chip 100 (FIG. 3); and c) bonding a cap 300 to substrate 200, the cap 300 covering chip 100, the heat dissipation layer 500 being in contact with cap 300, and the cap 300 and interconnection substrate 200 forming the chip package (FIG. 4).

The method further comprises, prior to step c), a step d) during which an element 400 made of an adhesive or solderable material is formed on cap 300 or the second surface 102 of chip 100 (as shown in FIG. 2). The positioning of the element 400 is selected so that, at step c), element 400 is positioned next to dissipation layer 500 and that they do not overlap. Dissipation layer 500 is positioned on a first part of the second surface 102 of chip 100. Element 400 is positioned on a second part of the second surface 102 of chip 100. The first part preferably corresponds to the central zone of second surface 102 and the second part preferably corresponds to the peripheral zone of second surface 102. Element 400 and dissipation layer 500 may be adjacently arranged or separated by a gap.

According to a first embodiment, element 400 is formed on the second surface 102 of chip 100 as shown in FIG. 2. Preferably, this step is carried out between step a) FIG. 1 and step b) FIG. 3. Element 400 enables to contain, partially or totally, dissipation layer 500 during its forming during step b).

According to a second embodiment, element 400 is formed on cap 300 so that, during step c), element 400 covers a second part of the second surface 102 of chip 100.

The implementation of step d) enables to position element 400, which acts as a wedge between cap 300 and chip 100, and enables to correctly position cap 300 at the desired height relative to chip 100.

Further, with such a method, the uniformity (thickness and surface area covered) of dissipation layer 500 is controlled. The obtained electronic device 1000 has a very good heat dissipation. The bond line thickness (BLT) is easily controlled by adjusting the thickness of element 400.

Further, an excellent adhesion between dissipation layer 500 and cap 300 is obtained. The device has a better mechanical strength, which avoids delamination problems. The lifetime as well as the performance of the component are improved.

There will now be described in further detail the different steps of this process and the different elements used to obtain electronic device 1000.

The assembly provided at step a) FIG. 1 comprises a chip 100 assembled on an interconnection substrate 300 by means of contact pads 110.

Chip 100 comprises a first main surface 101 (bottom face) and a second main surface 102 (top surface).

The first main surface 101 is arranged opposite interconnection substrate 200.

Chip 100 may comprise a substrate, inside and/or on top of which integrated circuits and/or discrete electronic elements, such as transistors, are formed, and an interconnection stack formed by a stack of insulating and conductive layers located on the side of the first surface 101 of chip 100. For example, the substrate is a semiconductor substrate, in particular made of silicon. These different elements/different parts are not shown on the drawings for a better readability.

Chip 100 is mounted to the substrate 200 in what is commonly referred to as a “flip chip” orientation, that is, the active portion of chip 100 with the contact pads arranged facing the front of interconnection substrate 200.

Contact pads 110 are arranged on the lower surface 101 of chip 100, on the side of the interconnection stack.

The connection between chip 100 and interconnection substrate 200 is performed via the contact pads 110 of the chip. Chip 100 may comprise a plurality of contact pads 110. Chip 100 may comprise at least some ten contact pads 110, for example, at least some hundred contact pads 110. As an example, the contact pads 110 are regularly distributed on the lower surface 101 of chip 100. They may be arranged in an array network.

Contact pads 110 are made of an electrically-conductive material. For example, contact pads 110 are made of a solderable material. Contact pads 110 are made, for example, of copper, silver, or tin, or of an alloy, for example based on tin and silver (SnAg).

A layer of electrically-insulating polymer 120 (referred to as an “underfill”) is positioned under chip 100, between interconnection substrate 200 and chip 100. Polymer layer 120 coats the connection pads 110 of the chip. This layer 120 enables to protect the mechanical integrity of pads 110 and protects them from oxidation. This coating layer 120 is, for example, an epoxy layer. It is injected after the transfer of chip 100 onto substrate 200 by capillarity.

Interconnection substrate 200 enables to assemble chip 100 to an external device according to a so-called surface-mount technique.

Substrate 200 may have, in top view, a substantially square or rectangular shape. As an example, substrate 200 is, in top view, larger than chip 100. Substrate 200 may have dimensions in top view greater than 10 mm by 10 mm and smaller than 110 mm by 110 mm, for example in the order of 25 mm by 25 mm.

Substrate 200 comprises, for example, a stack of different insulating layers 210 and of different metal layers 220 to form interconnects between the two main surfaces of substrate 200. Substrate 200 may comprise, for example, horizontal metal tracks in the orientation of FIG. 1 and/or vertical metal vias in the orientation of FIG. 1.

In the different drawings and in the different embodiments, a single chip 100 is shown between substrate 200 and cap 300. However, it is possible to have a plurality of chips between substrate 200 and cap 300.

Additional passive electronic devices, not shown, such as for example resistors, inductors, and capacitors, may be mounted to substrate 200 around chip 100.

During step b) FIG. 3, a dissipation layer 500 made of a thermal interface material (or TIM) is deposited on a first part of the second surface 102 of chip 100. Preferably, it is the central part of the second surface 102 of chip 100.

Layer 500 has, for example, a thermal conductivity higher than that of air. Layer 500 is, for example, a layer of paste, grease, or thermal adhesive.

The TIM material is, for example, a composite comprising a polymer, such as a polysiloxane (or silicone), and thermally-conductive fillers. The fillers are, for example, silver particles.

A TIM material is, for example, marketed by Wacker.

The material may also be deposited in the form of a serpentine shape, in the form of an ‘X’ shape, or in any other suitable form. During the positioning of cover 300, the deposited material will spread in the form of a layer. The greater the contact area, on the one hand, between chip 100 and the TIM material, and, on the other hand, between cap 300 and the TIM material, the more the heat dissipation will be improved.

Heat dissipation layer 500 enables to dissipate the heat generated by chip 100 during its operation towards metal cap 300 and thus towards the outside of device 1000.

The method comprises a step d) during which an element 400 made of an adhesive or solderable material is positioned either on cap 300 or on chip 100 as shown in FIG. 2.

According to a first alternative embodiment, element 400 is positioned on chip 100, and more particularly on the second surface 102 of chip 100.

According to this first variant, step d) is preferably carried out before step b). Element 400 may play the role of a barrier during the forming of dissipation layer 500 and prevent for the TIM material to flow out of the second surface 102 of chip 100.

According to a second alternative embodiment, element 400 is positioned on cap 300 (i.e., on the underside surface of the cap). It is positioned so that, once cap 300 has been assembled on chip 100, it is positioned on a second part of the second surface 102 of the chip. In other words, it will be positioned adjacent to dissipation layer 500.

According to this second variant, step d) may be carried out before or after step b), but certainly before step c) FIG. 4.

According to a specific embodiment, element 400 is made of a solderable material, in particular of metal or of a metal alloy. It is preferably made of gold or of copper. It will, for example, be soldered to cap 300 and/or to chip 100, preferably by ultrasonic soldering. A bonding layer (not shown) may be previously deposited on cap 300 and/or on the second surface 102 of chip 100 in order to make the surface of cap 300 and/or of chip 100 compatible with a soldering and/or to promote the mechanical strength of the element on cap 300 and/or on chip 100. The bonding layer is, for example, a gold layer.

According to another specific embodiment, element 400 is an adhesive material. It is a polymer or a composite comprising at least one polymer in which fillers may be dispersed.

The adhesive material is, for example, a B-stage polymer. The B-stage polymer is preferably an epoxy (also known as polyepoxide) or a (meth)acrylate. Once applied to cap 300 or to chip 100, a first heat treatment and/or UV treatment step (possibly followed by an anneal) enables to pre-polymerize the material. It thus acquires a certain rigidity and a certain adhesion. It is thus not only integral with cap 300 or with chip 100, but also rigid, and may be used as a wedge between cap 300 and chip 100. Once cap 300 has been positioned on substrate 100, a second polymerization step by means of a heat treatment and/or of a UV treatment (possibly followed by an anneal) enables to complete the polymerization of the B-stage material. This step may be carried out simultaneously with step c) or subsequently to step c). Cap 300 thus adheres to chip 100. For example, the first step is a heat treatment at a temperature in the range from 100 to 125° C. and the second step is a heat treatment at a 150° C. temperature.

The B-Stage material is marketed by companies such as Loctite, Delo, Henkel, and Sumimoto.

Alternatively, the adhesive material is a TIM material. The TIM material may be identical to or different from the TIM material of dissipation layer 500. Preferably, it is different. Once applied, a heat treatment or a UV treatment step enables to polymerize the material. It thus acquires a certain rigidity and a certain adhesion. It is thus not only integral with cap 300 or with chip 100, but also rigid, and may be used as a wedge.

The adhesive material (B-stage or TIM) may be deposited by jetting or by dispensing.

Element 400 (adhesive or solderable) may be deposited at once or in a plurality of layers. For example, in FIG. 5, two layers are deposited to form element 400. The number of deposited layers depends, in particular, on the desired thickness. In the case of a B-stage adhesive element, it is possible to perform a UV treatment or a treatment between each layer deposition, or at the end of the deposition of the different layers, in order to pre-polymerize it.

Element 400 may be continuous or discontinuous. It may form a continuous bead that will surround TIM layer 500 during step b) or c). Preferably, element 400 is discontinuous (FIGS. 6A, 6B, 6C, and 6D) to facilitate the degassing of material from dissipation layer 500. Element 400 may be in the form of pads (FIGS. 6A and 6D), of beads or strips, for example linear (FIG. 6B) or L-shaped (FIG. 6C). The various portions of element 400 may be positioned on the edges and/or in the corners of the second surface 102 of chip 100.

During step c), cap 300 (also called cover) is bonded to substrate 200. Cap 300 comprises a planar upper portion and side portions. The lower portion of the cap forms a rim intended to be bonded to substrate 200. Once positioned on substrate 200, cap 300 forms a cavity enabling to contain one or a plurality of chips 100. The inner surface of cap 300 partly delimits the cavity. The outer surface of the cap faces outwards.

Cap 300 particularly enables to dissipate the heat accumulated in electronic chip 100.

As an example, cap 300 has, in top view, a shape similar to the shape of substrate 200. It may have a substantially square or rectangular shape. The lateral dimensions of cap 300 are, for example, substantially identical to the lateral dimensions of substrate 200. Cap 300 is, for example, bonded to substrate 200 by means of a layer of adhesive 310. Preferably, cap 300 is bonded to substrate 200 in localized fashion, that is, adhesive layer 310 does not extend along the entire periphery of cap 300 and of substrate 200. In particular, cap 300 and substrate 200 may be bonded to each other via adhesive layer 310 only at their four corners.

Cap 300 may be formed by stamping.

Cap 300 is made of a thermally-conductive material. Preferably, cap 300 is a metal cap. It is, for example, made of copper. A plating, for example, with nickel, may cover cap 300.

During step c), cap 300 is bonded: to substrate 200 by means of a layer of adhesive 310 positioned between the edges of cap 300 and substrate 200, and to the chip due to dissipation layer 500 and due to adhesive or solderable element 400.

In the case where the material is an adhesive material, step c) is carried out, for example, according to the following sub-steps: positioning cap 300 on the assembly formed by chip 100 and interconnection substrate 200, and performing a heat treatment and/or an irradiation under ultraviolet radiation to polymerize the adhesive material.

The heat treatment and/or the irradiation with an ultraviolet radiation may simultaneously enable to polymerize the adhesive layer 310 positioned between cap 300 and substrate 200.

In the case where the material is a solderable material, step c) comprises the following sub-steps: positioning cap 300 on the assembly formed by chip 100 and interconnection substrate 200, performing a soldering sub-step, preferably an ultrasonic soldering, to solder cap 300 to chip 100, and performing a heat treatment and/or an irradiation under ultraviolet radiation to polymerize the adhesive layer 310 positioned between cap 300 and substrate 200.

The order of these last two sub-steps may be reversed.

Once step c) has been carried out, an electronic component 1000 capable of being assembled with an external element is obtained. Such a component 1000 is, for example, shown in FIG. 7.

Electronic component 1000 comprises a chip 100 having a first surface 101 and a second surface 102, the first surface 101 of chip 100 being bonded to a substrate 200 by connection pads 110. A cap 300 made of a thermally-conductive material is bonded to substrate 200, for example by an adhesive layer 310, and covers chip 100. A heat dissipation layer 500 made of a thermal interface material covers a first part of the second surface 102 of chip 100 and is in contact with cap 300.

The cap is further bonded to a second part of the second surface 102 of 100 chip by means of an element 400 made of an adhesive material or of a solderable material.

Cap 300 and interconnection substrate 200 form a package protecting chip 100 and enabling to electrically couple it to an external element (not shown in the drawings), for example an external device, or to a substrate of PCB (printed circuit board) type. Substrate 200 may be mounted and electrically connected to the external device, for example by means of interconnection pads 210 positioned on the second surface of substrate 200 (FIG. 7).

Interconnection pads 210 may be balls, pillars, or columns. Balls 210 are for example evenly distributed on the lower surface of substrate 200, for example in an array network. The lateral dimensions of the balls 210 and the pitch between balls 210 are, for example, respectively greater than the lateral dimensions of the contact pads 110 of the chip and greater than the pitch between pads 110 of the chip 100. Substrate 200 thus performs a function of spreading and redistribution of the contacts of the chip 100 towards the contacts of the external device.

Such electronic components, also known as TEFCBGA (for thermally enhanced flip-chip ball grid array) devices, are particularly advantageous for a wide range of applications.

They enable to form a large number of input/output (I/O) connections, with a good performance and heat dissipation.

The device is, for example, intended for the automotive industry. In particular, the device may be used in a microcontroller or in an advanced driver assistance system (ADAS).

It can be used in high-performance computing (HPC) devices, for example in central processing units (CPUs) or in graphics processing units (GPUs).

The device can, for example, be used in the industrial field. More particularly, the device for example aims at being used for the development of green energies or for the electrification of infrastructures, for example for charging stations or for solar energy.

The device may also be used in the field of the Internet of Things and of smart homes.

The device may also be used in the implementation of 5G networks, data centers, and servers.

The device is, for example, intended to be used in personal electronics, for example to increase the radio frequency content, in 5G connection devices or more generally in connected devices. The device is for example used in cell phones (‘smartphones’) or for Internet of Things networks. The device is for example connected by 5G or WIFI. The device for example comprises high-speed interfaces, for example with an advanced filtering and an electromagnetic discharge protection.

Various embodiments and variants have been described. Those skilled in the art will understand that certain features of these various embodiments and variants could be combined, and other variants will become apparent to those skilled in the art.

Finally, the practical implementation of the described embodiments and variants is within the abilities of those skilled in the art, based on the functional indications given hereabove.

1. A method of manufacturing an electronic device, comprising the following steps:
a) providing an assembly comprising a chip and an interconnection substrate, the chip having a first surface and a second surface, the first surface of the chip being assembled to the interconnection substrate by contact pads;
b) depositing a heat dissipation layer made of a thermal interface material on the second surface of the chip; and
c) bonding a cap to the substrate with the cap covering the chip and the heat dissipation layer being in contact with the cap;
the method further comprising a step d) during which an element made of an adhesive or solderable material is formed either on the chip prior to step b), or on the cap prior to step c), so that, during step c), the element is in contact with the cap and with the chip and is positioned next to the heat dissipation layer.

2. The method according to claim 1, wherein the element is made of a B-stage polymer material.

3. The method according to claim 2, wherein the B-stage polymer material is selected from among polyepoxides.

4. The method according to claim 2, wherein, step d) comprises depositing the B-stage polymer material and then pre-polymerizing the B-stage polymer material, and further comprising polymerizing the B-stage material during step c) or after step c).

5. The method according to claim 1, wherein the element is made of a thermal interface material that is identical to the thermal interface material of the heat dissipation layer.

6. The method according to claim 1, wherein the element is made of a thermal interface material that is different from the thermal interface material of the heat dissipation layer.

7. The method according to claim 1, wherein the element is made of a solderable metal material, and further comprising ultrasonically soldering the element to the cap during step d) and ultrasonically soldering the element to the second surface of the chip.

8. The method according to claim 1, wherein the element is made of a solderable metal material, and further comprising ultrasonically soldering the element to the second surface of the chip during step d) and ultrasonically soldering the element to the cap.

9. An electronic device, comprising:
an electronic chip arranged between an interconnection substrate and a cap;
wherein a first surface of the electronic chip comprises contact pads bonded to the interconnection substrate; and
wherein a heat dissipation layer and an element made of an adhesive material or of a solderable material are positioned on a second surface of the chip and in contact with the cap.

10. The device according to claim 9, wherein the element is made of a B-stage polymer material.

11. The device according to claim 10, wherein the B-stage polymer material is selected from among polyepoxides.

12. The device according to claim 9, wherein the element is made of a thermal interface material that is identical to the thermal interface material of the heat dissipation layer.

13. The device according to claim 9, wherein the element is made of a thermal interface material that is different from the thermal interface material of the heat dissipation layer.

14. The device according to claim 9, wherein the element forms strips or pads, positioned around the heat dissipation layer.

15. The device according to claim 9, wherein the cap is a metal cap.

16. The device according to claim 15, wherein metal cap is made of copper.

17. The device according to claim 9, wherein the element is made of a solderable material having one surface soldered to the second surface of the chip and another surface soldered to the cap.

18. A method of manufacturing an electronic device, comprising the following steps:
i) providing an assembly comprising a chip and an interconnection substrate, the chip having a first surface and a second surface, the first surface of the chip being assembled to the interconnection substrate by contact pads;
ii) forming a B-stage polymer material on either the second surface of the chip or an underside surface of a cap;
iii) pre-polymerizing the B-stage polymer material;
iv) depositing a heat dissipation layer made of a thermal interface material on the second surface of the chip;
v) bonding the cap to the substrate with the cap covering the chip and the heat dissipation layer being in contact with the cap and the cap forming a cavity containing the chip; and
vi) completing polymerization of the B-stage polymer material;
wherein step vi) is performed during or subsequent to step v).

19. The method according to claim 18, wherein the B-stage polymer material is selected from among polyepoxides.

20. A method of manufacturing an electronic device, comprising the following steps:
i) providing an assembly comprising a chip and an interconnection substrate, the chip having a first surface and a second surface, the first surface of the chip being assembled to the interconnection substrate by contact pads;
ii) ultrasonically soldering a metal material on one of the second surface of the chip or an underside surface of a cap;
iii) depositing a heat dissipation layer made of a thermal interface material on the second surface of the chip;
iv) bonding the cap to the substrate with the cap covering the chip and the heat dissipation layer being in contact with the cap and the cap forming a cavity containing the chip; and
v) ultrasonically soldering the metal material to the other of the second surface of the chip or then underside surface of the cap;
wherein step v) is performed during or subsequent to step iv).

21. The method according to claim 20, wherein the metal material is made of copper or gold and an alloy thereof.
